(19) United States
(12) Patent Application Publication
(10) Pub. No.: US 2024/0355822 A1
(43) Pub. Date: Oct. 24, 2024

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Che Chi SHIH, Taoyuan City (TW); Tsung-En LEE, Taipei City (TW); Wu-Wei TSAI, Taoyuan City (TW); Wei-Yen WOON, Taoyuan City (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 18/304,393

(22) Filed: Apr. 21, 2023

(51) Int. Cl. H01L 27/092; H01L 21/02; H01L 21/8258; H01L 29/06; H01L 29/24; H01L 29/423; H01L 29/66; H01L 29/775

(52) U.S. Cl. CPC H01L 27/0922; H01L 21/02565; H01L 21/02603; H01L 21/8258; H01L 29/0673; H01L 29/24; H01L 29/42392; H01L 29/66969; H01L 29/775

(57) ABSTRACT

A semiconductor device includes a first transistor and a second transistor vertically stacked over the first transistor. The first transistor includes a semiconductor channel layer, a first gate structure wrapping around the semiconductor channel layer, and first source/drain structures on opposite ends of the semiconductor channel layer. The second transistor includes a metal oxide channel layer, a second gate structure wrapping around the metal oxide channel layer, and second source/drain structures on opposite ends of the metal oxide channel layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 17B illustrate a method in various stages of forming a semiconductor device in accordance with some embodiments of the present disclosure.

FIGS. 18A to 19B illustrate a method in various stages of forming semiconductor device in accordance with some embodiments of the present disclosure.

FIGS. 20A to 36B illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

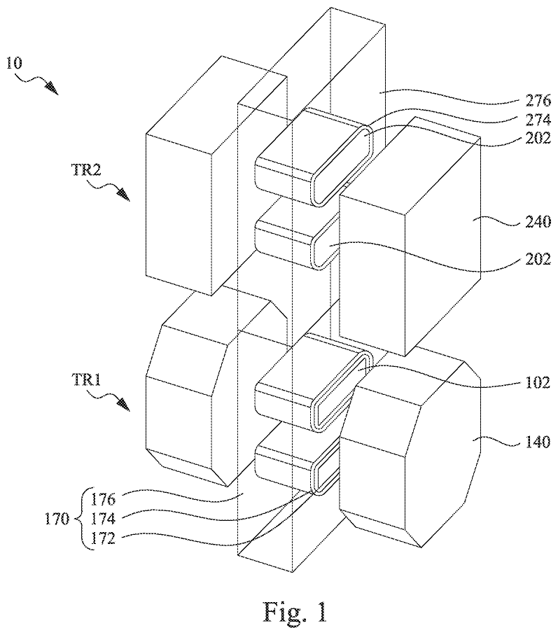

FIG. 1 is a perspective view of a semiconductor device in accordance with some embodiments of the present disclosure. In the present disclosure, a complementary FET (CFET) 10 is shown, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FET. The first transistor TR1 includes first channel layers 102 vertically stacked one above another, a first gate structure 170 wrapping around each of the first channel layers 102, and first source/drain structures 140 on opposite ends of each of the first channel layers 102. The first gate structure 170 may include an interfacial layer 172, a gate dielectric layer 174, and a gate electrode 176. Similarly, the second transistor TR2 includes second channel layers 202 vertically stacked one above another, a second gate structure 270 wrapping around each of the second channel layers 202, and second source/drain structures 240 on opposite ends of each of the second channel layers 202. The second gate structure 270 may include a gate dielectric layer 274 and a gate electrode 276. In some embodiments, the first transistor TR1 has a first conductivity type (e.g., p-type) and the second transistor TR2 has a second conductivity type (e.g., n-type) different from the first conductivity type. In some embodiments, the first transistor TR1 can be referred to as a P-FET, and the second transistor TR2 can be referred to as an N-FET.

In some embodiments, with respect to the first transistor TR1, the first channel layers 102 may be made of semiconductor material, and the first source/drain structures 140 may be made of epitaxy material. On the contrary, with respect to the second transistor TR2, the second channel layers 202 may be made of metal oxide, and the first source/drain structures 140 may be made of metal.

Exemplary metal oxide may include metal oxide that is suitable for n-type channel material, such as indium oxide (InOₓ), gallium oxide (GaOₓ), zinc oxide (ZnOₓ), tin oxide (SnOₓ), cadmium oxide (CdO), nickel oxide (NiO), copper oxide (CuO), scandium oxide (ScOₓ). Amorphous metal oxide may include large bandgap and still have high mobility, and may ignore the lattice mismatch with semiconductor material, such as silicon or silicon germanium. For example, In₂O₃ may be a potential candidate for n-channel. In some embodiments, an In₂O₃/SiO₂/Silicon back-gate nFET is provided, in which the In₂O₃ channel layer has 2.9 nm thickness. The On current Iₒₙ of the device can achieve about 340 μA/μm and on/off ratio>6 orders at gate length Lg of 5 μm. Moreover, the peak value of field effect mobility μ_{FE} is about 93.8 cm²/V*s.

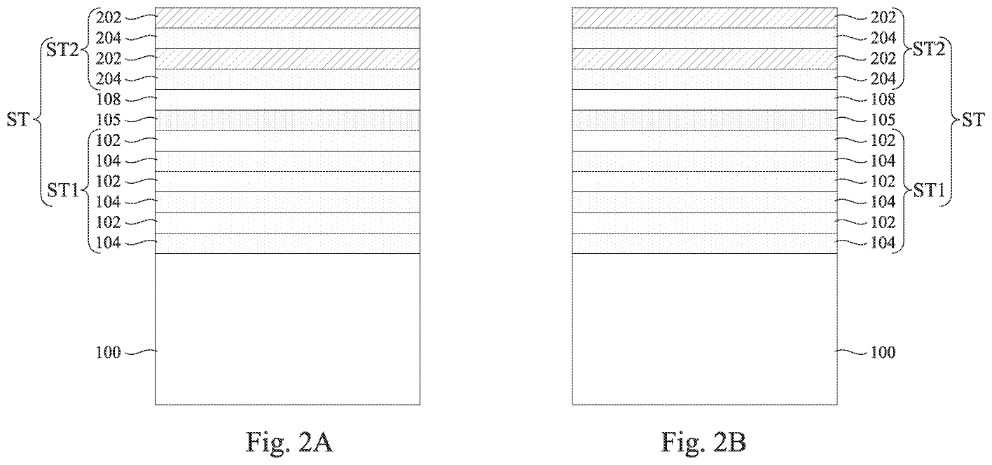

FIGS. 2A to 17B illustrate a method in various stages of forming a semiconductor device in accordance with some embodiments of the present disclosure. It is noted that FIGS. 2A, 3A, 4A, 5A, 6A, 7A, 8A, 9A, 10A, 11A, 12A, 13A, 14A, 15A, 16A, and 17A are cross-sectional views along line A-A of FIG. 1, and FIGS. 2B, 3B, 4B, 5B, 6B, 7B, 8B, 9B. 10B, 11B, 12B, 13B, 14B, 15B. 16B, and 17B are cross-sectional views along line A-A of FIG. 1. Although FIGS. 2A to 17B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 17B may be similar to those described with respect to FIG. 1, and thus relevant details will not be repeated for brevity.

Reference is made to FIGS. 2A and 2B. Shown there is a substrate 100.

Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A stack ST is formed over the substrate 100. The stack ST includes a first stack ST1 of alternating semiconductor layers 102 and sacrificial layers 104. The stack ST further includes a semiconductor layer 105 over the first stack ST1. The stack ST further includes a semiconductor layer 108 over the semiconductor layer 105. The stack ST further includes a second stack ST2 of alternating metal oxide layers 202 and sacrificial layers 204. In some embodiments, the sacrificial layers 104 and 204 may be removed during the following replacement gate (RPG) process.

In some embodiments, the semiconductor layers 102 and the semiconductor layer 108 may be made of pure silicon layers that are free of germanium. The semiconductor layers 102 and the semiconductor layer 108 may also be substantially pure silicon layers, for example, with a germanium percentage lower than about 1 percent. In some embodiments, the semiconductor layer 108 made of pure silicon may ensure a better crystalline quality of the overlaying sacrificial layer 204.

The sacrificial layers 104, the semiconductor layer 105, and the sacrificial layers 204 may be made of silicon germanium, while the semiconductor layer 105 may include a higher germanium composition than the sacrificial layers 104 and 204. For example, the germanium percentage (atomic percentage concentration) of the semiconductor layer 105 is in a range from about 60 percent and about 80 percent, and the germanium percentage (atomic percentage concentration) of the sacrificial layers 104 and 204 is in a range from about 20 percent and about 40 percent. In some embodiments, the sacrificial layers 104 and 204 can also be referred to as semiconductor layers.

In some embodiments, the metal oxide layers 202 may include metal oxide that is suitable for n-type channel material, such as indium oxide (InOₓ), gallium oxide (GaOₓ), zinc oxide (ZnOₓ), tin oxide (SnOₓ), cadmium oxide (CdO), nickel oxide (NiO), copper oxide (CuO), scandium oxide (ScOₓ). Accordingly, the metal oxide layers 202 can be referred to as metal oxide channel layers or metal-containing channel layers. In some embodiments, the semiconductor layers 102 may include silicon, while the metal oxide layers 202 may be free of silicon. Moreover, the sacrificial layers 204 may include germanium, while the metal oxide layers 202 may be free of germanium.

In some embodiments, the metal oxide layers 202 may include an amorphous structure. In some embodiments, the amorphous structure allows the metal oxide layer 202 being successfully grown on silicon surface or silicon germanium surface (e.g., the sacrificial layers 104) without lattice mismatch concern. On the contrary, the semiconductor layers 102 may include crystalline structure.

In some embodiments, the semiconductor layers 102, the sacrificial layers 104, the semiconductor layer 105, the semiconductor layer 108, the sacrificial layers 204 may be deposited using suitable deposition process, such as selective epitaxial growth (SEG), chemical vapor deposition (CVD), molecular beam epitaxy (MBE), or other suitable process(es). In some embodiments, the metal oxide layers 202 may be deposited using suitable deposition process, such as chemical vapor deposition (CVD), atomic layer deposition (ALD), or other suitable process(es).

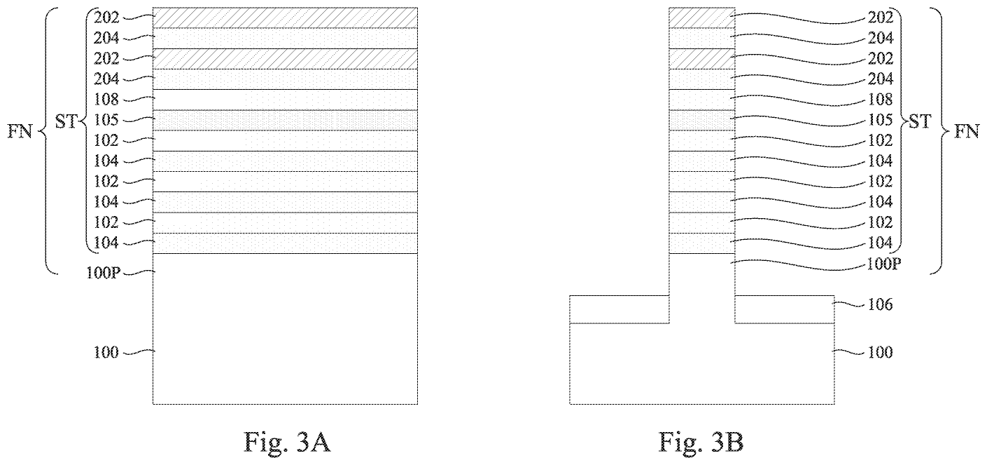

Reference is made to FIGS. 3A and 3B. A patterning process is performed to the stack ST and the substrate 100 to form a fin structure FN. In some embodiments, the patterning process may include forming a patterned photoresist layer over the stack ST, and then performing an etching process to remove unwanted portions of the stack ST and the substrate 100 exposed by the patterned photoresist layer. The fin structure FN may include a remaining portion of the stack ST and a semiconductor strip 100P protruding over the substrate 100. In some embodiments, the etching process may include wet etch, dry etch, or the like.

After the fin structure FN is formed, isolation structures 106 are formed over the substrate 100 and laterally surrounding the fin structure FN. In some embodiments, the isolation structures 106 may be in contact with sidewalls of the semiconductor strip 100P of the substrate 100. The isolation structures 106 may be shallow trench isolation (ST1) structures, suitable isolation structures, combinations of the foregoing, or the like. In some embodiments, the isolation structures 106 may be made of oxide (e.g., silicon oxide), nitride (e.g., silicon nitride), or combinations thereof.

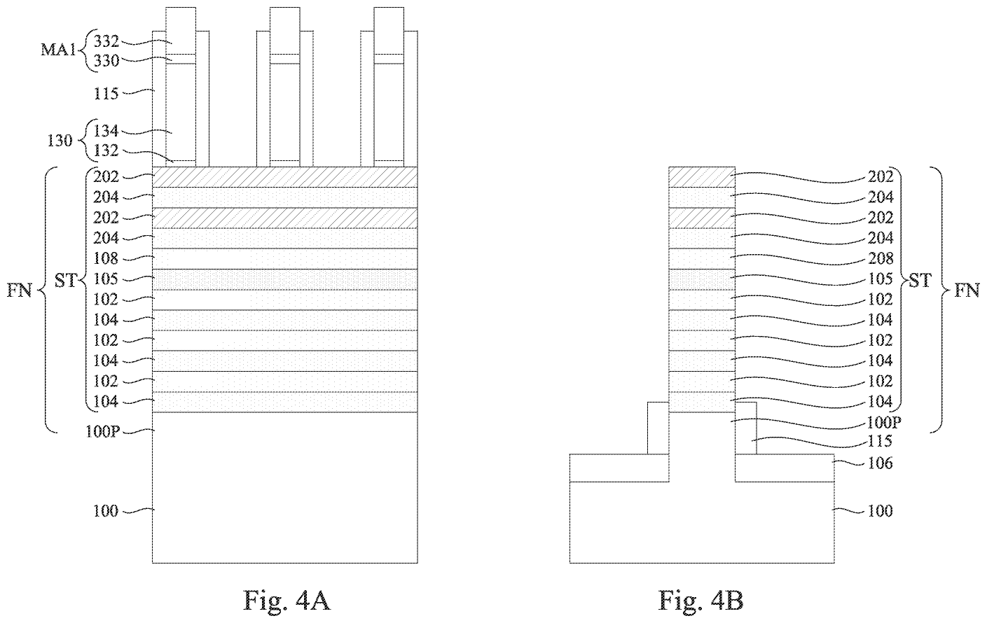

Reference is made to FIGS. 4A and 4B. Dummy gate structures 130 are formed over the substrate 100 and crossing the fin structure FN. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of each of the dummy gate structures 130 (see FIG. 4A), and on opposite sidewalls of the fin structure FN (see FIG. 4B). In some embodiments, portions of the spacers 115 on opposite sidewalls of each of the dummy gate structures 130 can be referred to as gate spacers, and portions of the spacers 115 on opposite sidewalls of the fin structure FN can be referred to as fin spacers. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130 and on sidewalls of the fin structure FN. In some embodiments, the remaining vertical portions of the spacer layer can be referred to as the spacers 115. The spacer layer may be deposited using techniques such CVD, ALD, or the like.

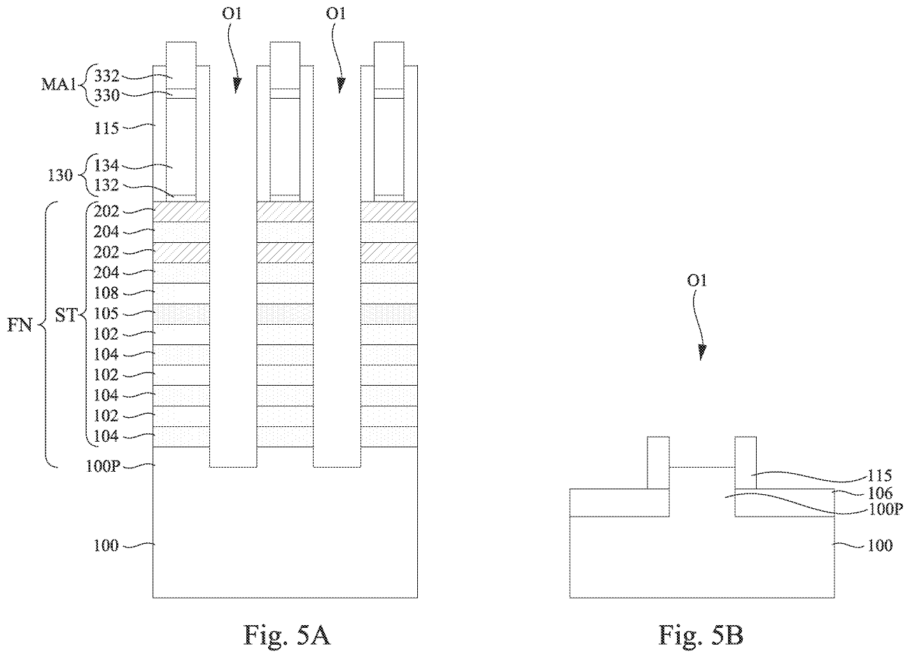

Reference is made to FIGS. 5A and 5B. An etching process is performed to remove portions of the fin structure FN (or stack ST) by using the dummy gate structures 130 and the spacers 115 as etch mask, so as to form source/drain openings O1 in the fin structure FN (or in the stack ST). In some embodiments, the etching process may be wet etch, dry etch, or combinations thereof.

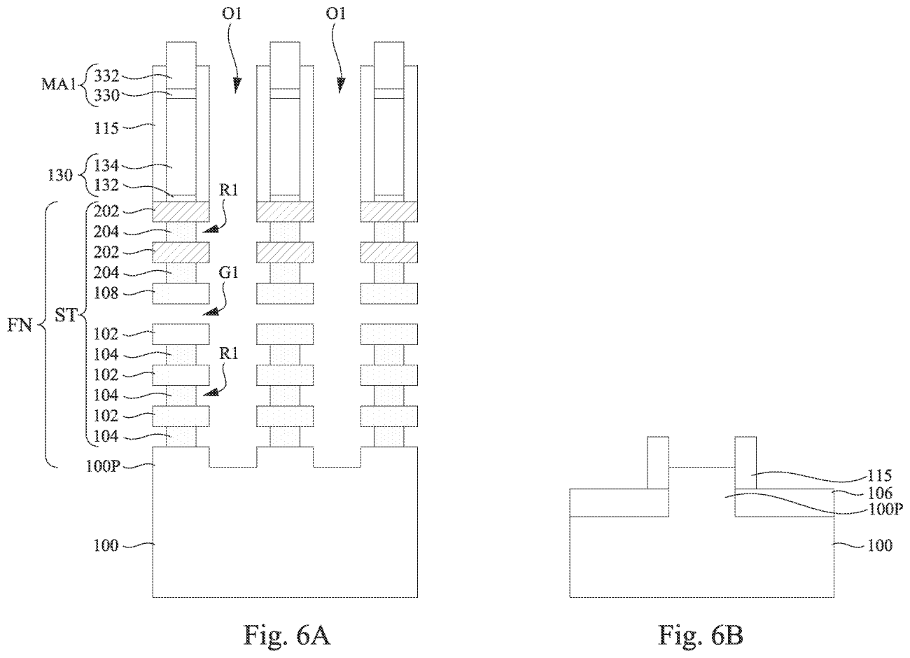

Reference is made to FIGS. 6A and 6B. After the source/drain openings O1 are formed, the sacrificial layers 104 and the sacrificial layers 204 are laterally etched to form sidewall recesses R1. Moreover, the semiconductor layer 105 is removed to form a gap G1 vertically between the topmost semiconductor layer 102 and the semiconductor layer 108. In some embodiments, the gap G1 may spatially connect the source/drain openings O1 on opposite sides of the dummy gate structure 130.

In some embodiments, the sidewalls of the sacrificial layers 104 and the sacrificial layers 204 may be etched using isotropic etching processes, such as wet etching or the like. In some embodiments, because the semiconductor layer 105 includes higher germanium concentration than the sacrificial layers 104 and the sacrificial layers 204, an etchant can be properly selected such that an entirety of the semiconductor layer 105 is removed.

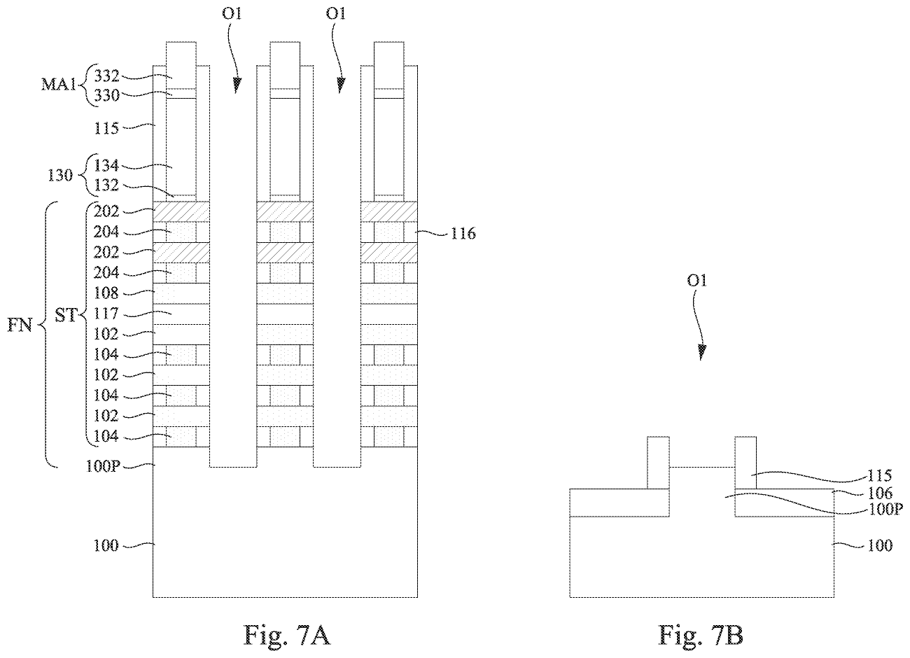

Reference is made to FIGS. 7A and 7B. Inner spacers 116 are formed in the sidewall recesses R1 on opposite ends of each of the sacrificial layers 104 and the sacrificial layers 204, and an isolation layer 117 is formed in the gap G1. In some embodiments, the inner spacers 116 and the isolation layer 117 may be formed by, for example, depositing a dielectric layer blanket over the substrate 100 and filling the sidewall recesses R1 and the gap G1, and then performing an anisotropic etching to remove portions of the dielectric layer outside the sidewall recesses R1 and the gap G1, leaving the remaining portions of the dielectric layer in the sidewall recesses R1 and the gap G1 as the inner spacers 116 and the isolation layer 117, respectively. The inner spacers 116 and the isolation layer 117 may be deposited by a conformal deposition process, such as CVD, ALD, or the like. The dielectric layer may include a material such as SIN, SiOCN, SiCN, SIOC, although any suitable material, such as low-dielectric constant (low-k) materials having a k-value less than about 3.5, may be utilized.

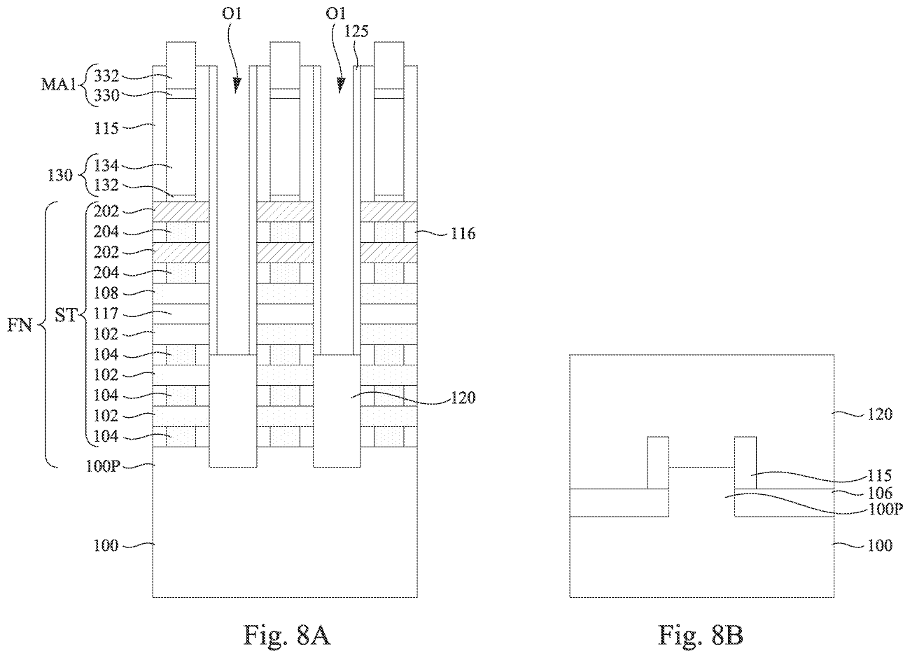

Reference is made to FIGS. 8A and 8B. Dummy materials 120 are formed in the source/drain openings O1. In greater detail, the dummy materials 120 may be formed at lower portions of the source/drain openings O1, such that the top surfaces of the dummy materials 120 may be lower than the bottommost metal oxide layer 202. As a result, the sidewalls of the metal oxide layers 202 may be exposed through the upper portions of the source/drain openings O1 once the dummy materials 120 are formed. In some embodiments, the dummy materials 120 may be formed by, for example, depositing a dielectric material filling the source/drain openings O1, and then etching back the dielectric material to lower the top surface of the dielectric material to a desired position. In some embodiments, the dummy materials 120 may be made of SiOCN, or other suitable material.

Afterwards, liners 125 are formed lining sidewalls of the upper portions of the source/drain openings O1, so as to cover the sidewall surfaces of the metal oxide layers 202. The liners 125 may also cover the sidewalls of the spacers 115. In some embodiments, the liners 125 may be formed by, for example, depositing a liner layer blanket over the substrate, an anisotropic etching process is performed to remove horizontal portions of the liner layer, such that vertical portions of the liner layer remain on sidewalls of the metal oxide layers 202 and the spacers 115. In some embodiments, the remaining vertical portions of the liner layer can be referred to as the liners 125. In some embodiments, the liners 125 may be made of SiN, metal oxide, or other suitable material.

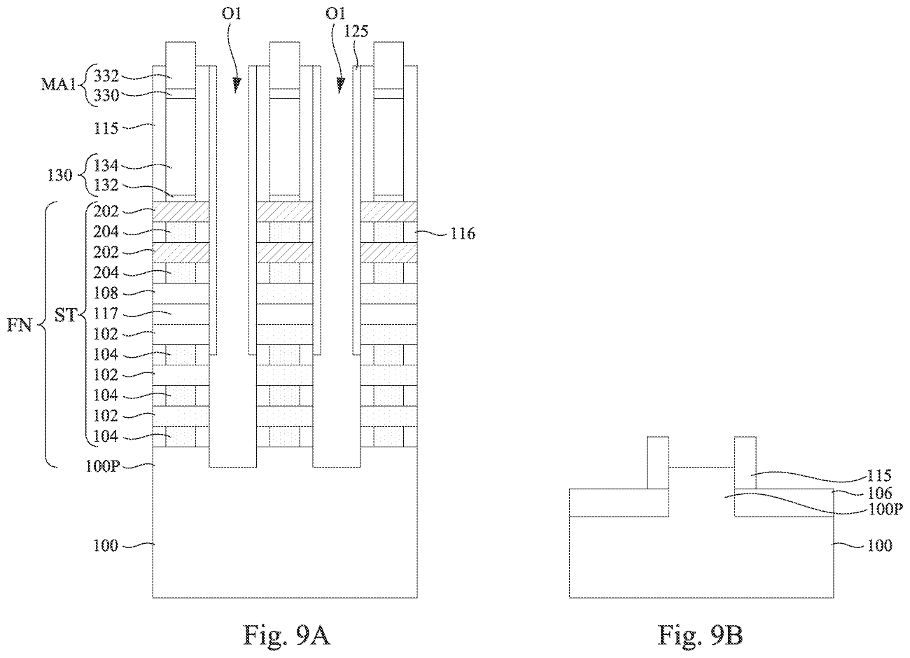

Reference is made to FIGS. 9A and 9B. The dummy materials 120 are removed by suitable etching process, so as to expose the sidewalls of the semiconductor layers 102 through the lower portions of the source/drain openings O1. In some embodiments, the liners 125 may include a higher etching resistance to the etching process than the dummy materials 120, and thus the liners 125 may remain after the dummy materials 120 are removed.

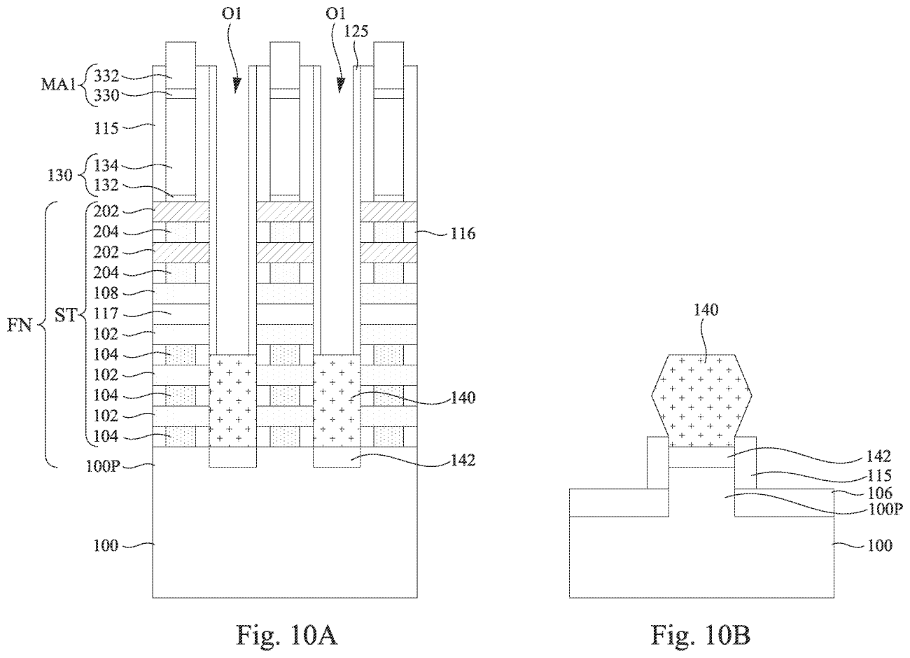

Reference is made to FIGS. 10A and 10B. Epitaxy layers 142 are formed at bottoms of the source/drain openings O1, and then first source/drain structures 140 are formed over the epitaxy layers 142, respectively. In some embodiments, the formation of the epitaxy layers 142 may include a plurality of deposition cycles, in which each deposition cycle may include a selective epitaxial growth (SEG) process and an etching process. In some embodiments, the SEG process may selectively grow a semiconductor material on exposed semiconductor surfaces, such as the exposed surfaces of the semiconductor strips 100P and the exposed surfaces of the semiconductor layers 102. However, because the exposed areas of the semiconductor strips 100P are greater than the exposed area of each of the semiconductor layers 102, the semiconductor material may include higher growing rate on the exposed areas of the semiconductor strips 100P than on the exposed area of each of the semiconductor layers 102. That is, a greater amount of the semiconductor material will be grown on the exposed areas of the semiconductor strips 100P than on the exposed area of each of the semiconductor layers 102. As a result, the etching process in each deposition cycle of the epitaxy layers 142 may remove portions of the semiconductor material formed on the exposed area of each of the semiconductor layers 102, while portions of the semiconductor material may remain over the semiconductor strips 100P after the etching process. Accordingly, performing several deposition cycles may allow a bottom-up deposition for the epitaxy layers 142. That is, the epitaxy layers 142 may be formed from the bottoms of the source/drain openings O1 via a bottom-up manner.

The first source/drain structures 140 may be formed by suitable deposition process, such as a selective epitaxial growth (SEG) process. In some embodiments, the SEG process may selectively grow a semiconductor material on exposed semiconductor surfaces, such as the exposed surfaces of the epitaxy layers 142 and the exposed surfaces of the semiconductor layers 102. In some embodiments, an implantation process may be performed to the first source/drain structures 140. For example, the first source/drain structures 140 may be doped with p-type dopants, such as boron (B), gallium (Ga), indium (In), aluminium (Al), or the like. In some embodiments, the epitaxy layers 142 may be formed without performing an implantation process, and thus the epitaxy layers 142 and 242 are un-doped. In some embodiments, the first source/drain structures 140 can also be referred to as source/drain epitaxy structures.

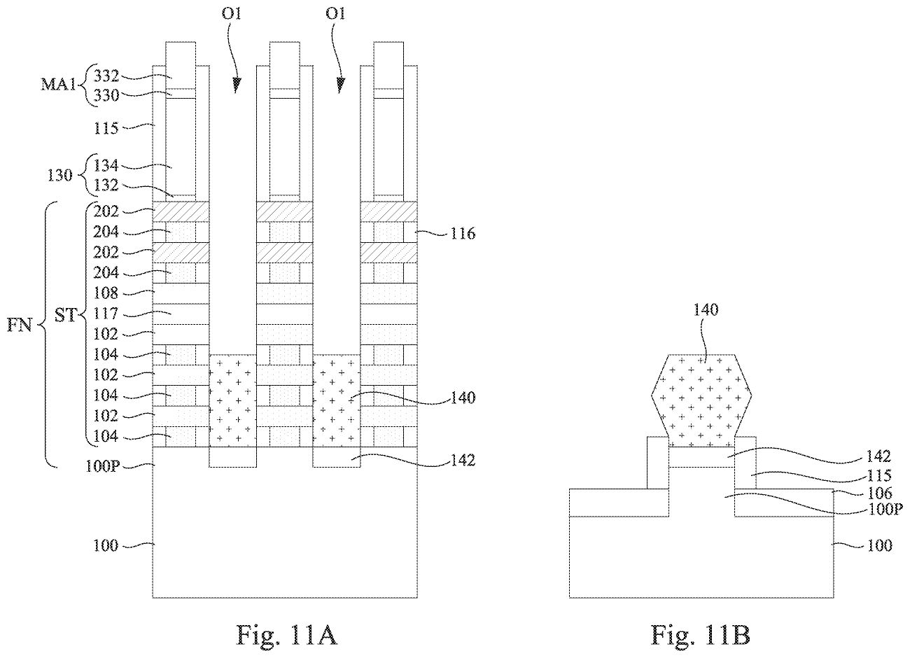

Reference is made to FIGS. 11A and 11B. After the first source/drain structures 140 are formed, the liners 125 are removed through suitable etching process. After the liners 125 are removed, the sidewalls of the metal oxide layers 202 are exposed.

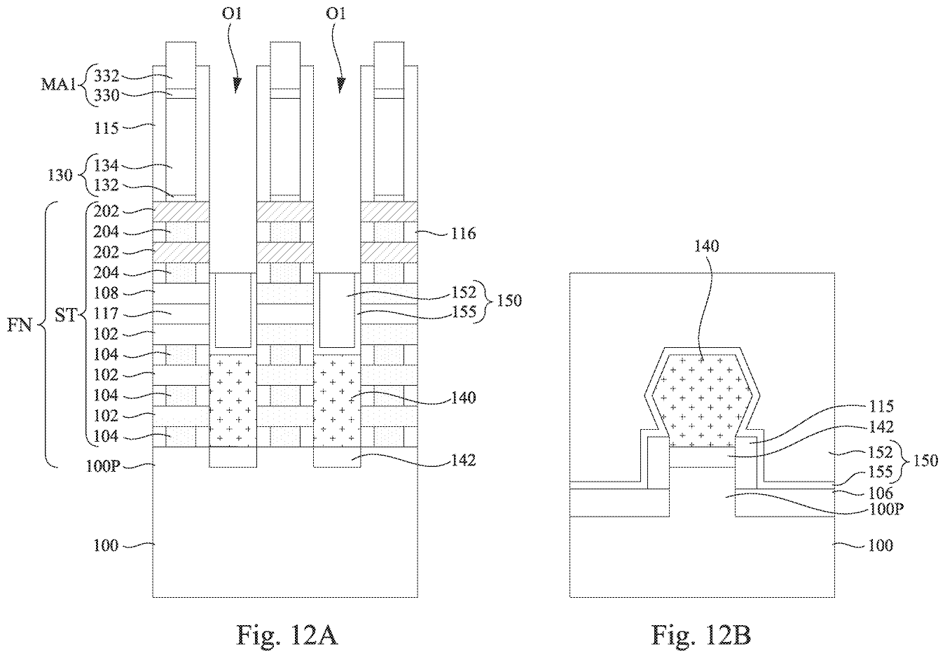

Reference is made to FIGS. 12A and 12B. A contact etch stop layer (CESL) 155 is formed covering the first source/drain structures 140. Afterwards, an interlayer dielectric (ILD) layer 152 is formed over the CESL 155. Then, an etching back process is performed to lower top surfaces of the CESL 155 and the ILD layer 152, such that sidewalls of the metal oxide layers 202 are exposed through the source/drain openings O1. In some embodiments, the CESL 155 and the ILD layer 152 can be collectively referred to as an isolation structure 150. In some embodiments, the semiconductor layer 108 and the isolation layer 107 are in contact with the CESL 155 of the isolation structure 150.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

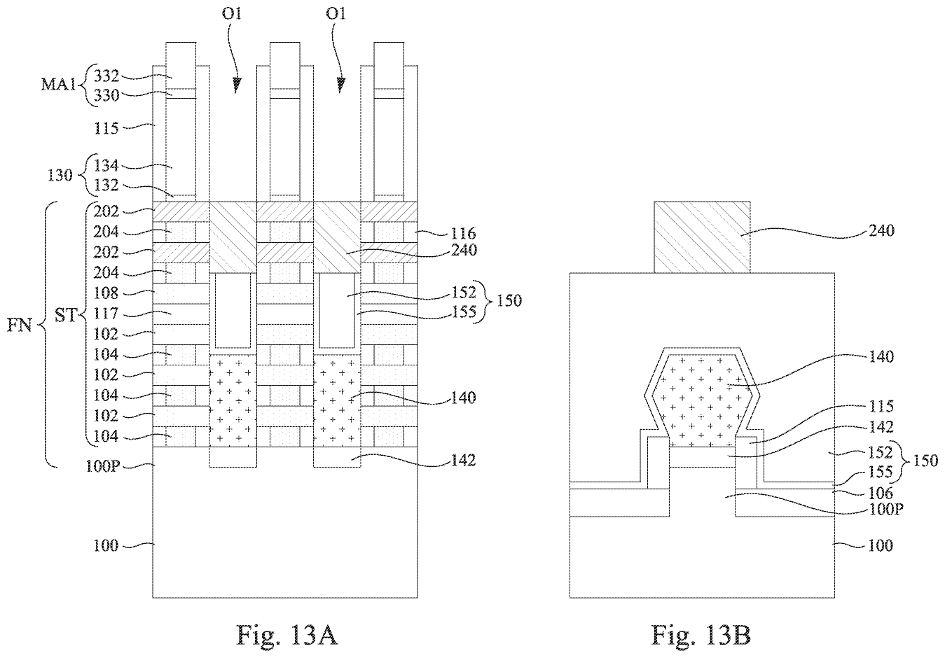

Reference is made to FIGS. 13A and 13B. Second source/drain structures 240 are formed on opposite ends of each of the metal oxide layers 202. In some embodiments, the second source/drain structures 240 may be made of metal, and can also be referred to as source/drain metals. The second source/drain structures 240 may be formed by, for example, depositing a metal layer in the source/drain openings O1, and then patterning the metal layer. In some embodiments, the second source/drain structures 240 may include nickel (Ni), tungsten (W), ruthenium (Ru), molybdenum (Mo), platinum (Pt), or the like.

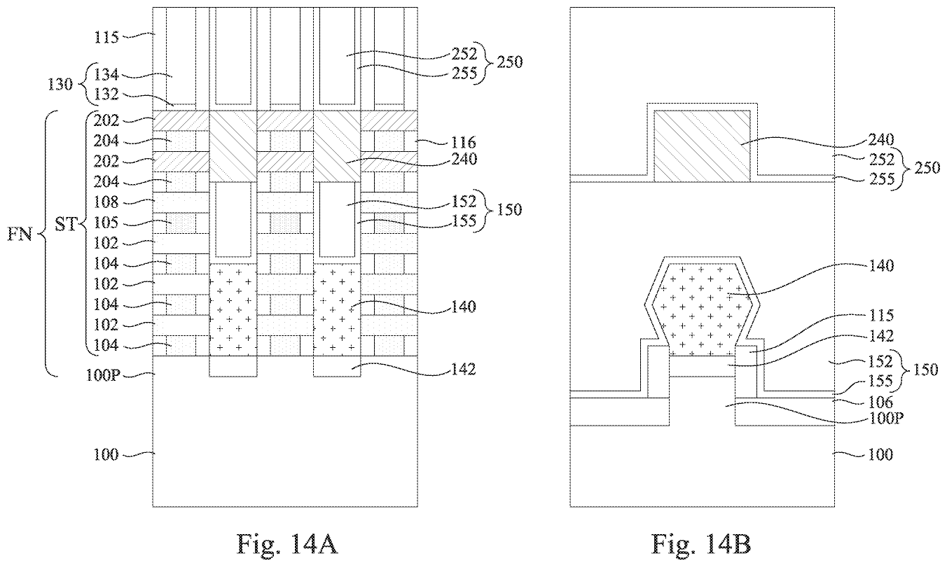

Reference is made to FIGS. 14A and 14B. A contact etch stop layer (CESL) 255 is formed covering the second source/drain structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 130 are exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively, and thus relevant details will not be repeated for brevity. In some embodiments, the isolation structures 150 and 250 may collectively form a composite isolation structure.

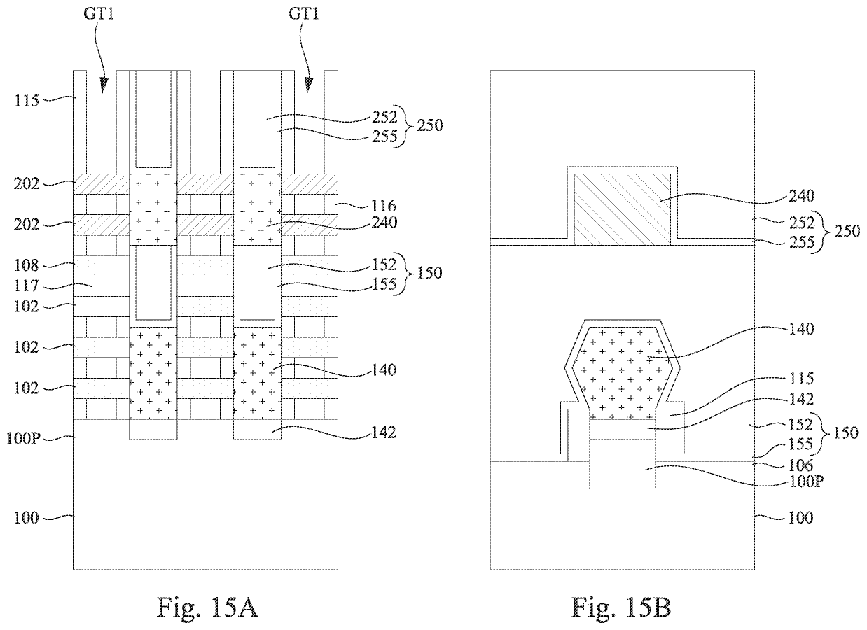

Reference is made to FIGS. 15A and 15B. The dummy gate structures 130 are removed to form gate trenches GT1 between each pair of the spacers 115. Then, an etching process is performed to remove the sacrificial layers 104 and 204 through the gate trenches GT1, such that that the semiconductor layers 102 and the metal oxide layers 202 are suspended over the substrate 100.

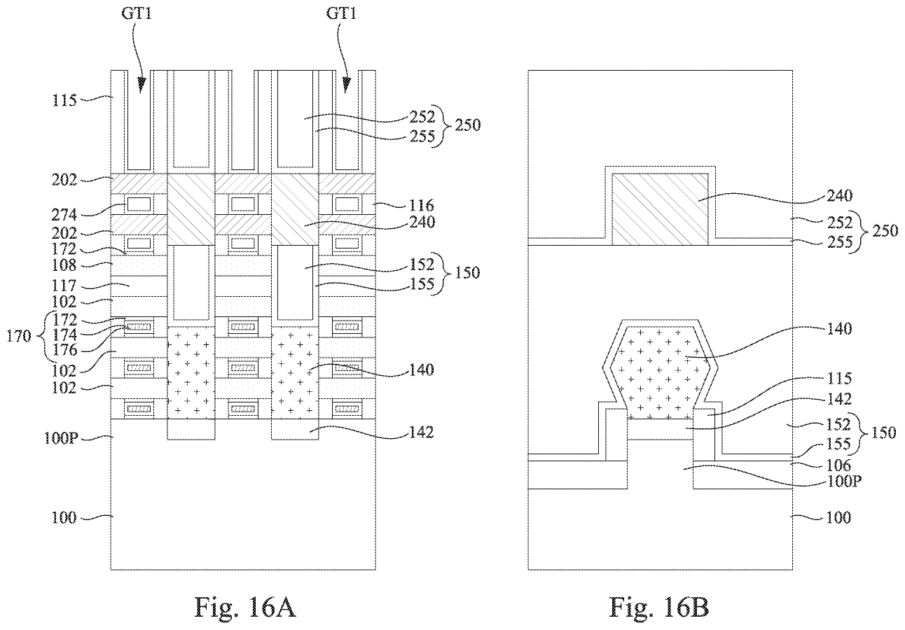

Reference is made to FIGS. 16A and 16B. Interfacial layers 172 are formed on exposed surfaces of the semiconductor layers 102, respectively. In some embodiments, the interfacial layers 172 may be made of oxide, such as silicon oxide (SiO₂), or the like. The interfacial layers 172 are formed using thermal oxidation, such that the interfacial layers 172 are selectively formed on the exposed surfaces of the semiconductor layers 102. In some embodiments, the interfacial layers 172 may not be formed on the exposed surfaces of the metal oxide layers 202. In FIG. 16A, a portion of the interfacial layers 172 may also be formed on top surface of the semiconductor layer 108.

Afterwards, gate dielectric layers 174 are formed over the interfacial layers 172, and gate dielectric layers 274 are formed covering the exposed surfaces of the metal oxide layers 202. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layers 174 and 274 are formed by suitable deposition process, such as CVD, ALD, or the like. In some embodiments, the gate dielectric layers 174 and 274 may be formed through a single deposition process.

Afterwards, gate electrodes 176 are formed in the gate trenches GT1 and over the gate dielectric layers 174. The gate electrode 176 may include work function metal layer(s) and a filling metal. The work function metal layer may be an n-type or p-type work function layer. Exemplary p-type work function metals include TIN, TaN, Ru, Mo, Al, WN. ZrSi₂, MoSi₂, TaSi₂, NiSi₂, WN, other suitable p-type work function materials, or combinations thereof. Exemplary n-type work function metals include Ti, Ag. TaAl, TaAIC, TiAIN, TaC. TaCN, TaSIN, Mn, Zr, other suitable n-type work function materials, or combinations thereof. The work function layer may include a plurality of layers. The filling metal may include tungsten (W), aluminum (Al), copper (Cu), or another suitable conductive material(s).

The gate electrodes 176 are then etched back, such that the remaining gate electrodes 176 are at the lower portion of the gate trenches GT1. Accordingly, first gate structures 170 are formed. In greater detail, the first gate structures 170 may wrap around the respective semiconductor layers 102. In some embodiments, each of the first gate structures 170 may include the interfacial layer 172, the gate dielectric layer 174 over the interfacial layer 172, and the gate electrode 176 over the gate dielectric layer 174.

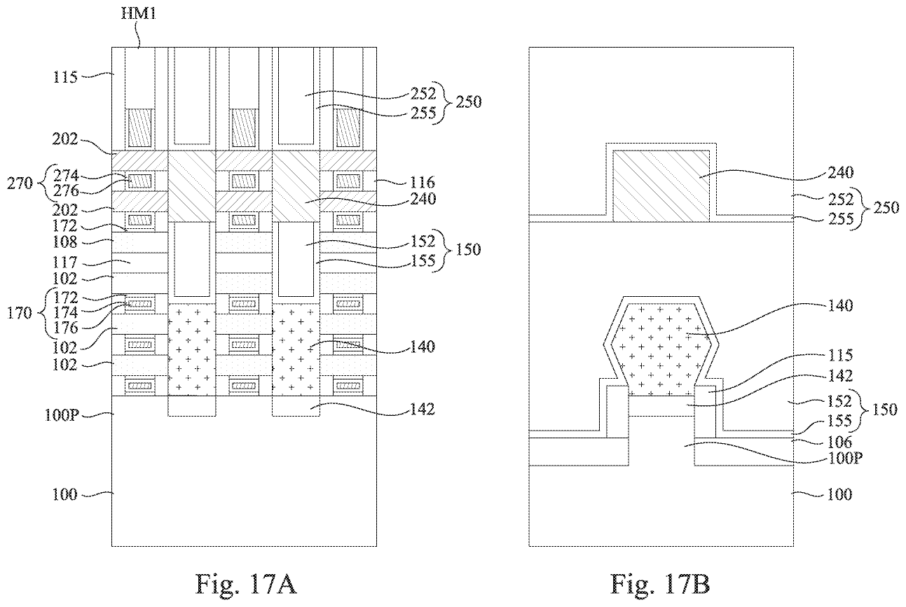

Reference is made to FIGS. 17A and 17B. Gate electrodes 276 are formed in the gate trenches GT1 and over the first gate structures 170. Accordingly, second gate structures 270 are formed. In greater detail, the second gate structures 270 are formed in upper portions of the gate trenches GT1 and above the first gate structures 170, such that the second gate structures 270 may wrap around the respective metal oxide layers 202. In some embodiments, each of the second gate structures 270 may include the gate dielectric layer 274 and the gate electrode 276 over the gate dielectric layer 274. The materials of the gate electrode 276 may be similar to those described with respect to the gate electrode 176, and thus relevant details will not be repeated for brevity.

The second gate structures 270 are then etched back, such that top surfaces of the second gate structures 270 are lower than top surfaces of the spacers 115. Afterwards, hard masks HM1 are formed over respectively second gate structures 270. In some embodiments, the hard masks HM1 may include one or more layers of insulating material such as silicon nitride based material including SIN, SiCN and SiOCN.

The first gate structure 170, the first source/drain structures 140 on opposite sides of the first gate structure 170, and the semiconductor layers 102 that are in contact with the first source/drain structures 140 may collectively serve as the first transistor TR1 as described in FIG. 1. In such condition, the semiconductor layers 102 that are in contact with the first source/drain structures 140 may also be referred to as channel layers of the first transistor TR1. Similarly, the second gate structure 270, the second source/drain structures 240 on opposite sides of the second gate structure 270, and the metal oxide layers 202 that are in contact with the second source/drain structures 240 may collectively serve as the second transistor TR2 as described in FIG. 1. In such condition, the metal oxide layers 202 that are in contact with the second source/drain structures 240 may also be referred to as channel layers of the second transistor TR2. In FIG. 17A, opposite ends of the topmost semiconductor layer 102 is in contact with the isolation structure 150, and is not in contact with the first source/drain structures 140. Thus, the topmost semiconductor layer 102 may not function as a channel layer of the first transistor TR1. Instead, the topmost semiconductor layer 102, the isolation layer 117, and the semiconductor layer 108 may collectively serve as an isolation structure vertically between the first gate structure 170 and the second gate structure 270.

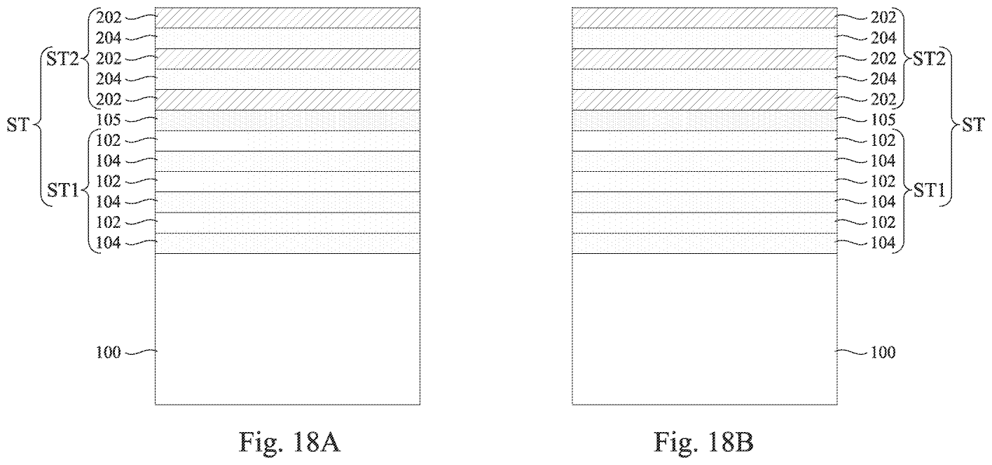

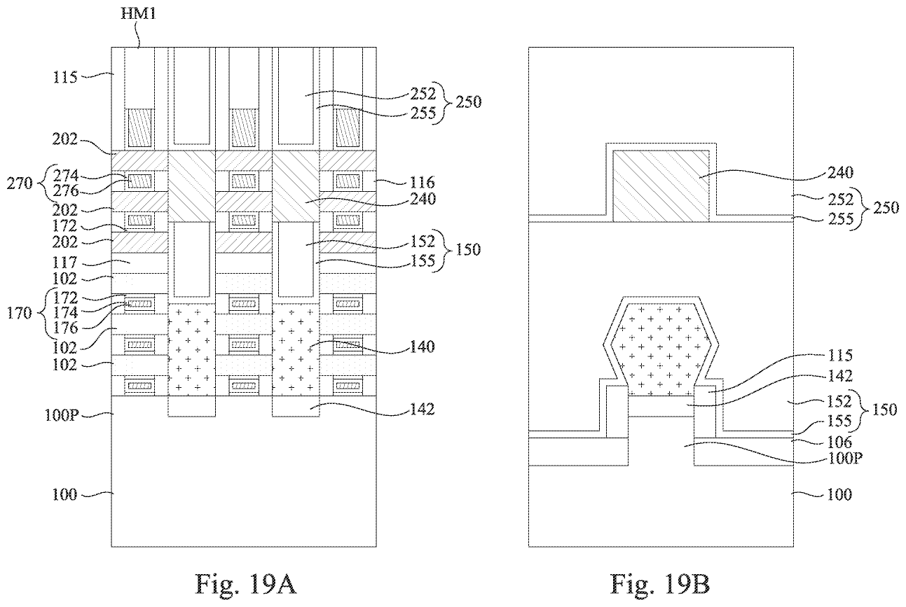

FIGS. 18A to 19B illustrate a method in various stages of forming a semiconductor device in accordance with some embodiments of the present disclosure. It is noted that FIGS. 18A and 19A have a same cross-sectional view as FIGS. 2A to 17A, and FIGS. 18B and 19B have a same cross-sectional view as FIGS. 2B to 17B. It is noted that some elements described in FIGS. 18A to 19B may be similar to those described with respect to FIGS. 2A to 17B, such elements are labeled the same, and relevant details will not be repeated for brevity.

Reference is made to FIGS. 18A and 18B. FIGS. 18A and 18B are similar to FIGS. 2A and 2B, the difference between the embodiments of FIGS. 18A and 18B and the embodiments of FIGS. 2A and 2B is that the semiconductor layer 108 of FIGS. 2A and 2B is replaced with a metal oxide layer 202. That is, the second stack ST2 of alternating metal oxide layers 202 and sacrificial layers 204 is directly formed over the semiconductor layer 105, in which the bottommost layer of the second stack ST2 is a metal oxide layer 202.

Moreover, different from the embodiments of FIGS. 2A and 2B, the sacrificial layers 204 of FIGS. 18A and 18B may be made of dielectric material, such as silicon oxide (SiO₂), silicon nitride (SiN), silicon carbon nitride (SiCN), silicon oxycarbonitride (SiOCN), or the like. If the channel layers are made of an epitaxial material (e.g., the semiconductor layers 102), the corresponding sacrificial layers (e.g., the sacrificial layers 104) need to be an epitaxial material to ensure a better crystalline quality during the epitaxial growth. However, if the channel layers are not made of an epitaxial material (e.g., the metal oxide layers 202), the corresponding sacrificial layers (e.g., the sacrificial layers 204) can be made of other materials, such as dielectric, instead of an epitaxial material. This is because there is no lattice mismatch issue between the metal oxide layers 202 and the sacrificial layers 204. Thus, the material of the sacrificial layers 104 can be properly selected to simplify the manufacturing process or to obtain a desired property (e.g., etching selectivity between the metal oxide layers 202 and the sacrificial layers 204).

Reference is made to FIGS. 19A and 19B. The structure shown in FIGS. 18A and 18B may undergo the processes as described with respect to FIGS. 3A to 17B, and the resulting structure is shown in FIGS. 19A and 19B. In FIG. 19A, the bottommost metal oxide layer 202 may be in contact with the isolation structure 150, and is not in contact with the second source/drain structures 240. Thus, the bottommost metal oxide layer 202 may not function as a channel layer of the second transistor TR2. Instead, the topmost semiconductor layer 102, the isolation layer 117, and bottommost metal oxide layer 202 may collectively serve as an isolation structure vertically between the first gate structure 170 and the second gate structure 270.

In some embodiments, because the sacrificial layers 104 and the sacrificial layers 204 may be made of epitaxial material and dielectric material, respectively. During a nanowire release process (e.g., the process discussed in FIGS. 15A and 15B), different etchants may be used to sequentially remove the sacrificial layers 104 and the sacrificial layers 204. For example, a first etching process is performed to remove the sacrificial layers 104, and then a second etching process is performed to remove the sacrificial layers 204, in which the first and second etching processes may include different etchants and may be performed at different time points. In some embodiments, the first etching process may be performed prior to or after the second etching process.

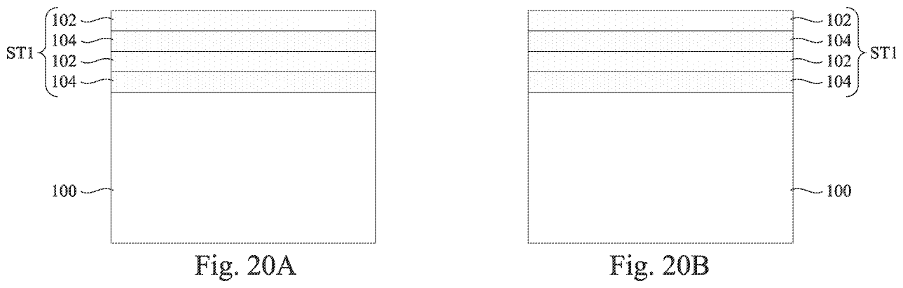

FIGS. 20A to 36B illustrate a method in various stages of forming a semiconductor device in accordance with some embodiments of the present disclosure. It is noted that FIGS. 20A, 21A, 22A, 23A, 24A, 25A, 26A, 27, 28A, 29A, 30A, 31A, 32A, 33A, 34A, 35A, and 36A include a same cross-sectional view as FIGS. 2A to 17A, and FIGS. 20B, 21B, 22B, 23B, 24B, 25B, 26B, 28B, 29B, 30B, 31B, 32B, 33B, 34B, 35B, and 36B include a same cross-sectional view as FIGS. 2B to 17B. Although FIGS. 20A to 36B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements and some processes of FIGS. 20A to 36B may be similar to those described with respect to FIG. 1 and FIGS. 2A to 17B, and thus relevant details will not be repeated for brevity.

Reference is made to FIGS. 20A and 20B. Shown there is a substrate 100. Then, a first stack ST1 of alternating semiconductor layers 102 and sacrificial layers 104 is formed over a substrate 100.

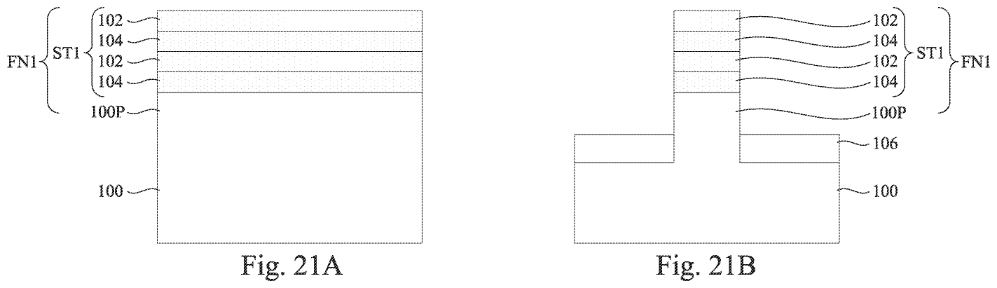

Reference is made to FIGS. 21A and 21B. A patterning process is performed to the first stack ST1 and the substrate 100 to form a fin structure FN1. The fin structure FN1 may include a remaining portion of the first stack ST1 and a semiconductor strip 100P protruding over the substrate 100. After the fin structure FN1 is formed, isolation structures 106 are formed over the substrate 100 and laterally surrounding the fin structure FN1.

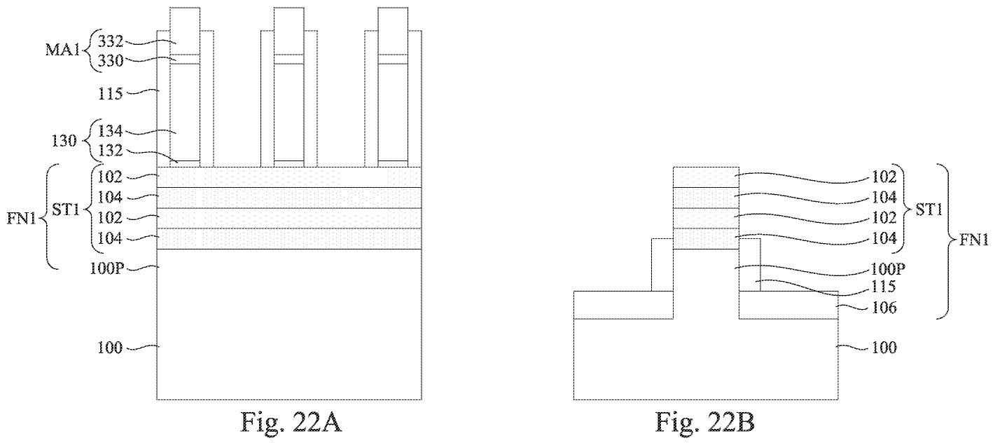

Reference is made to FIGS. 22A and 22B. Dummy gate structures 130 are formed over the substrate 100 and crossing the fin structure FN1. In some embodiments, patterned masks MA1 are disposed over the dummy gate structures 130. Spacers 115 are formed on opposite sidewalls of each of the dummy gate structures 130 (see FIG. 22A), and on opposite sidewalls of the fin structure FN1 (see FIG. 22B). In some embodiments, portions of the spacers 115 on opposite sidewalls of each of the dummy gate structures 130 can be referred to as gate spacers, and portions of the spacers 115 on opposite sidewalls of the fin structure FN1 can be referred to as fin spacers.

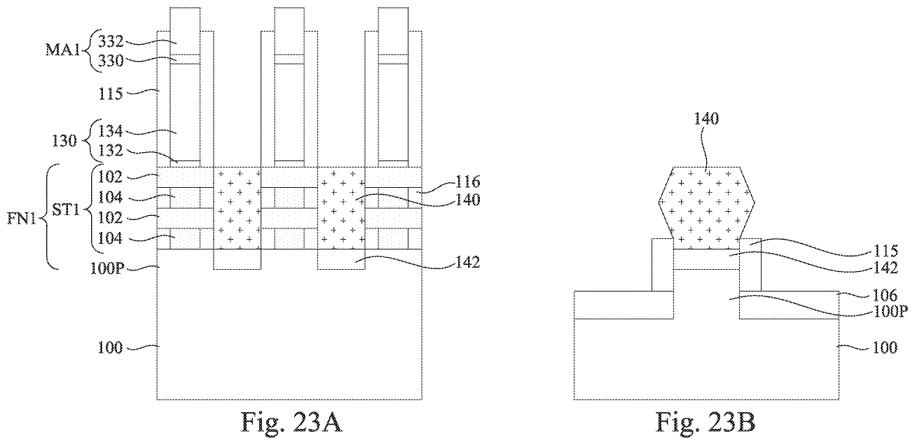

Reference is made to FIGS. 23A and 23B. An etching process is performed to remove portions of the fin structure FN1 (or stack ST1) by using the dummy gate structures 130 and the spacers 115 as etch mask, so as to form source/drain openings. Then, the sacrificial layers 104 are laterally etched to form sidewall recesses, and inner spacers 116 are formed in the sidewall recesses on opposite ends of each of the sacrificial layers 104. Afterwards, epitaxy layers 142 are formed at bottoms of the source/drain openings O1, and then first source/drain structures 140 are formed over the epitaxy layers 142, respectively.

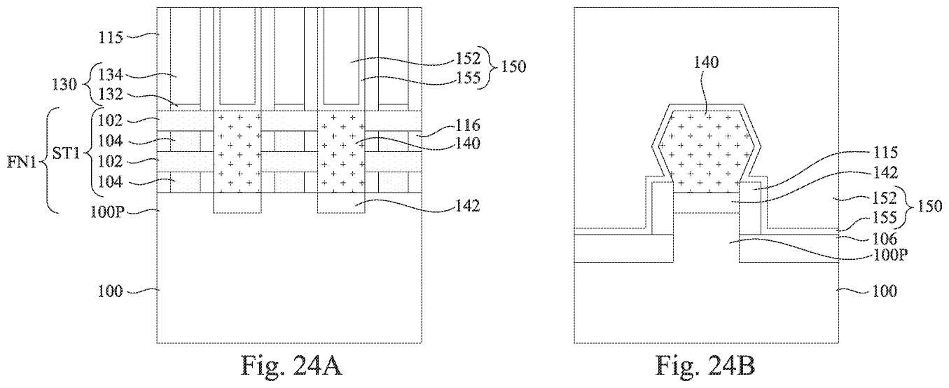

Reference is made to FIGS. 24A and 24B. A contact etch stop layer (CESL) 155 is formed covering the first source/drain structures 140. Afterwards, an interlayer dielectric (ILD) layer 152 is formed over the CESL 155. Then, a planarization process, such as CMP, is performed to the ILD layer 152 and the CESL 155 until the dummy gate structures 130 are exposed. In some embodiments, the CESL 155 and the ILD layer 152 can be collectively referred to as an isolation structure 150.

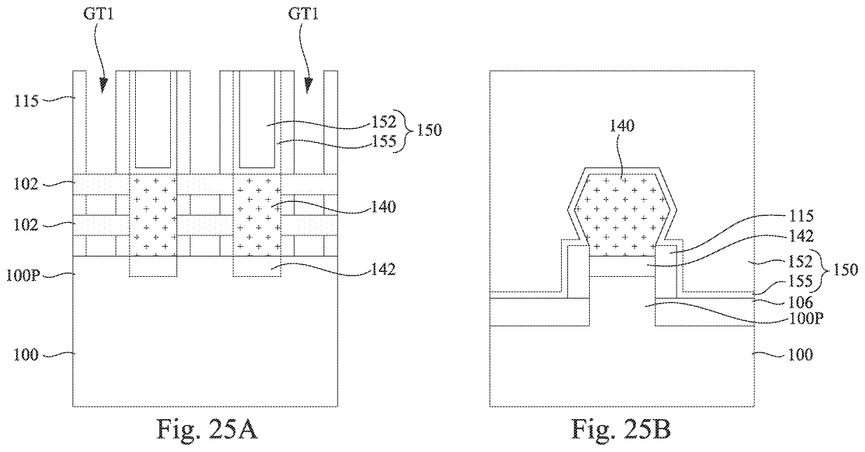

Reference is made to FIGS. 25A and 25B. The dummy gate structures 130 are removed to form gate trenches GT1 between each pair of the spacers 115. Then, an etching process is performed to remove the sacrificial layers 104 through the gate trenches GT1, such that that the semiconductor layers 102 are suspended over the substrate 100.

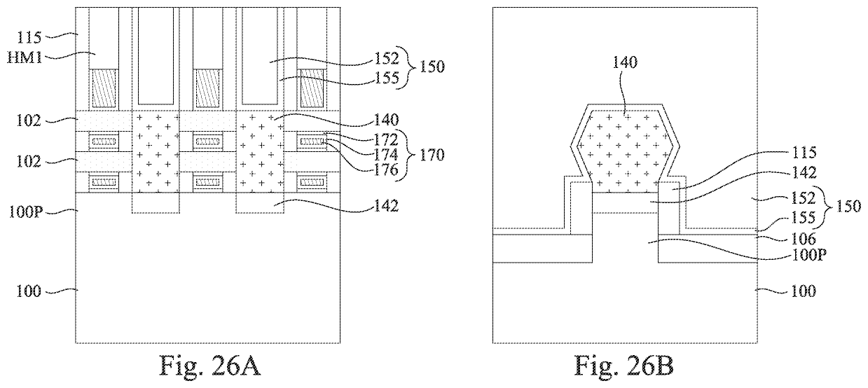

Reference is made to FIGS. 26A and 26B. Interfacial layers 172 are formed on exposed surfaces of the semiconductor layers 102, respectively. Afterwards, gate dielectric layers 174 are formed over the interfacial layers 172, and gate electrodes 176 are formed over the gate dielectric layers 174. Accordingly, first gate structures 170 are formed, in which each of the first gate structures 170 includes an interfacial layer 172, a gate dielectric layer 174, and a gate electrode 176. A planarization process, such as CMP, is performed to remove the excess gate dielectric layers 174 and the excess gate electrodes 176 until the ILD layer 152 is exposed.

The first gate structures 170 are then etched back, such that top surfaces of the first gate structures 170 are lower than top surfaces of the spacers 115. Afterwards, hard masks HM1 are formed over the respectively first gate structures 170.

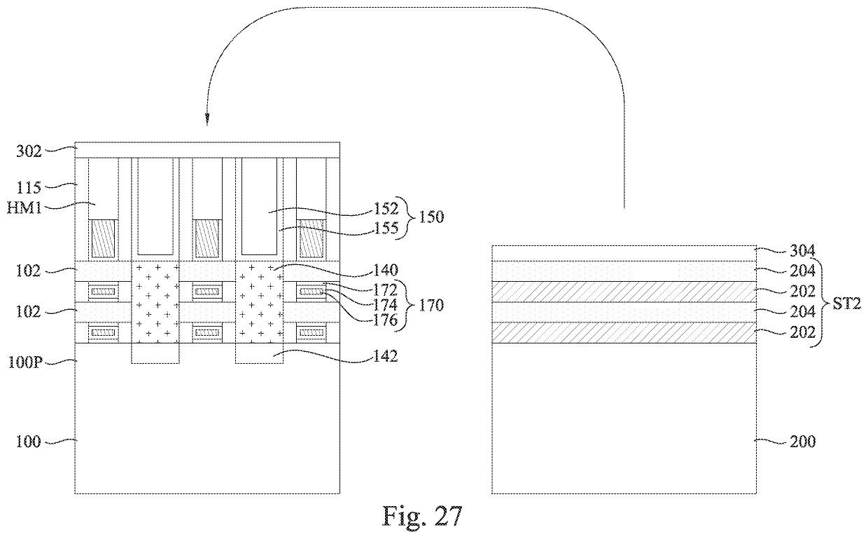

Reference is made to FIG. 27. A bonding layer 302 is formed over the structure shown in FIGS. 26A and 26B. In greater detail, the bonding layer 302 may be in contact with the hard masks HM1, the spacers 115, and the isolation structures 150. In some embodiments, the bonding layer 302 may be deposited over the structure shown in FIGS. 26A and 26B using suitable deposition process, such as CVD, PVD, ALD, or the like.

On the other hand, a substrate 200 is provided. The substrate 200 may include a similar material as the substrate 100. A second stack ST2 of alternating metal oxide layers 202 and sacrificial layers 204 are formed over the substrate 200. In some embodiments, the materials of the metal oxide layers 202 and sacrificial layers 204 have been described above, and thus relevant details will not be repeated for brevity. In some embodiments, the sacrificial layers 204 may include dielectric materials as discussed in FIGS. 18A and 18B.

A bonding layer 304 is formed over the second stack ST2. In some embodiments, the bonding layer 304 is in contact with a sacrificial layer 204. The bonding layers 302 and 304 may include dielectric material such as silicon oxide (SiOₓ), silicon dioxide (SiO₂), or other suitable materials. In some embodiments, the bonding layers 302 and 304 may include a same bonding material. In other embodiments, the bonding layers 302 and 304 may include different bonding materials.

The substrate 100 will be bonded to the substrate 200 as indicated by the arrow shown in FIG. 27. In greater detail, the substrate 100 will be bonded to the substrate 200 through the bonding layers 302 and 304, which will be discussed later.

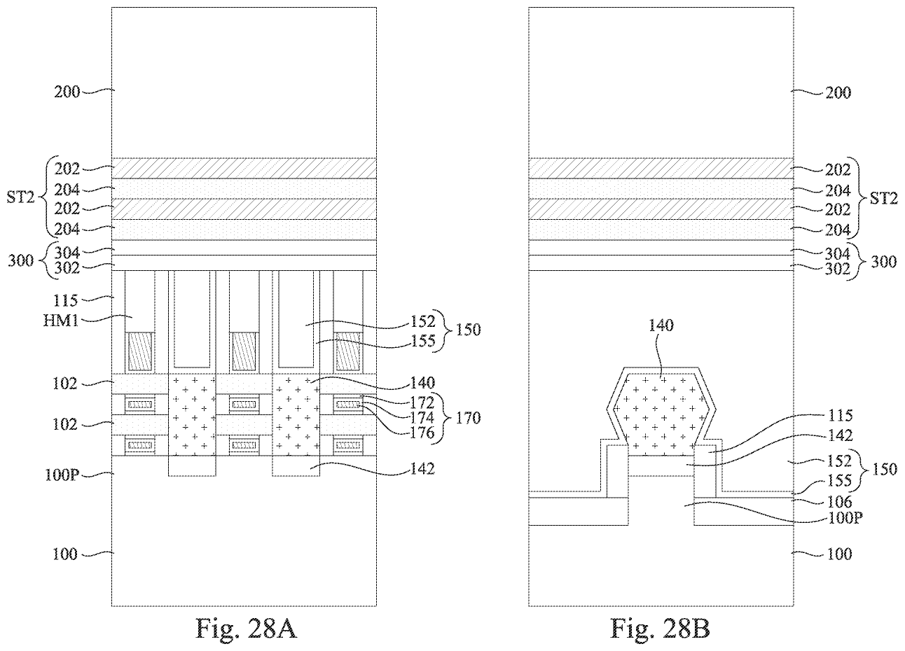

Reference is made to FIGS. 28A and 28B. The substrate 100 is bonded to the substrate 200. For example, in FIGS. 28A and 28B, the substrate 200 is flipped over by 180 degrees, such that the bonding layer 304 on the substrate 200 faces the bonding layer 302 on the substrate 100.

Then, the bonding layers 302 and 304 are bonded with each other using a suitable technique. In some embodiments, the bonding process may further include applying surface treatments to the surfaces of the bonding layers 302 and 304, respectively. The surface treatment may include a plasma treatment. The plasma treatment may be performed in a vacuum environment. After the plasma treatment, the surface treatment may further include a cleaning process (e.g., a rinse with deionized water, or the like) that may be applied to the bonding layers 302 and 304. The bonding layers 302 and 304 are pressed against each other to initiate a pre-bonding of the substrates 100 and 200. The pre-bonding may be performed at room temperature (between about 21 degrees and about 25 degrees). After the pre-bonding, an annealing process may be applied to the bonding layers 302 and 304 that have already been pressed against each other. The annealing process results in an increased bonding force between the bonding layers 302 and 304, such that even if the bonding layers 302 and 304 are no longer subjected to the pressing force, they will not delaminate or peel from each other. In some embodiments, the bonding layers 302 and 304 can be collectively referred to as a bonding structure.

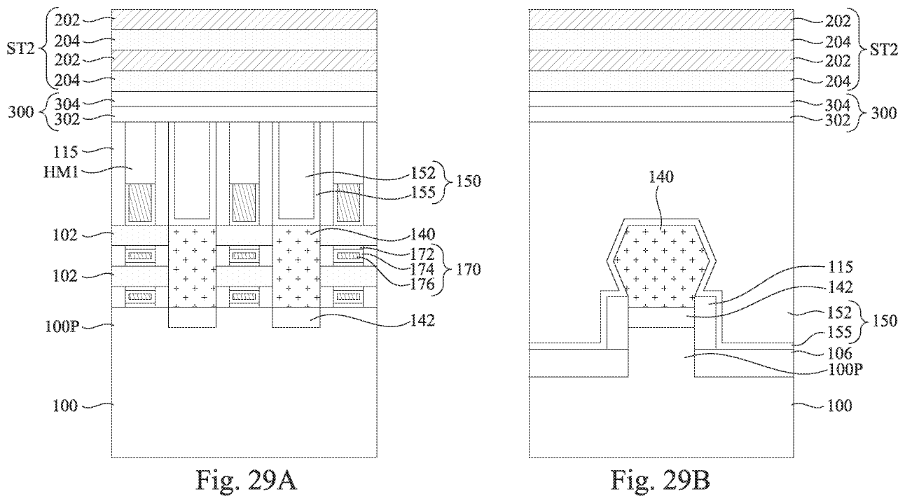

Reference is made to FIGS. 29A and 29B. A grinding process is performed on the backside of the substrate 200 (see FIGS. 28A and 28B), so as to remove the substrate 200 until the topmost sacrificial layer 204 is exposed.

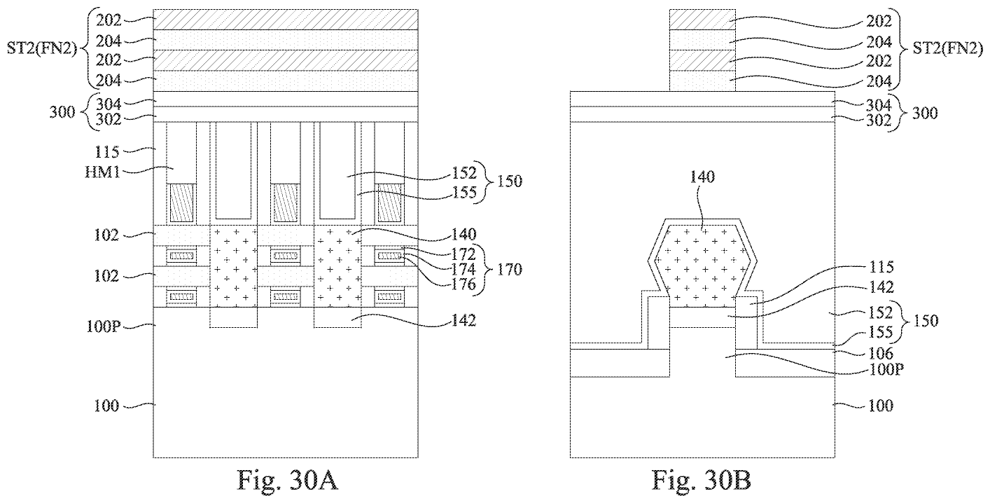

Reference is made to FIGS. 30A and 30B. A patterning process is performed to the second stack ST2 to form a fin structure FN2. The fin structure FN2 may include a remaining portion of the second stack ST2.

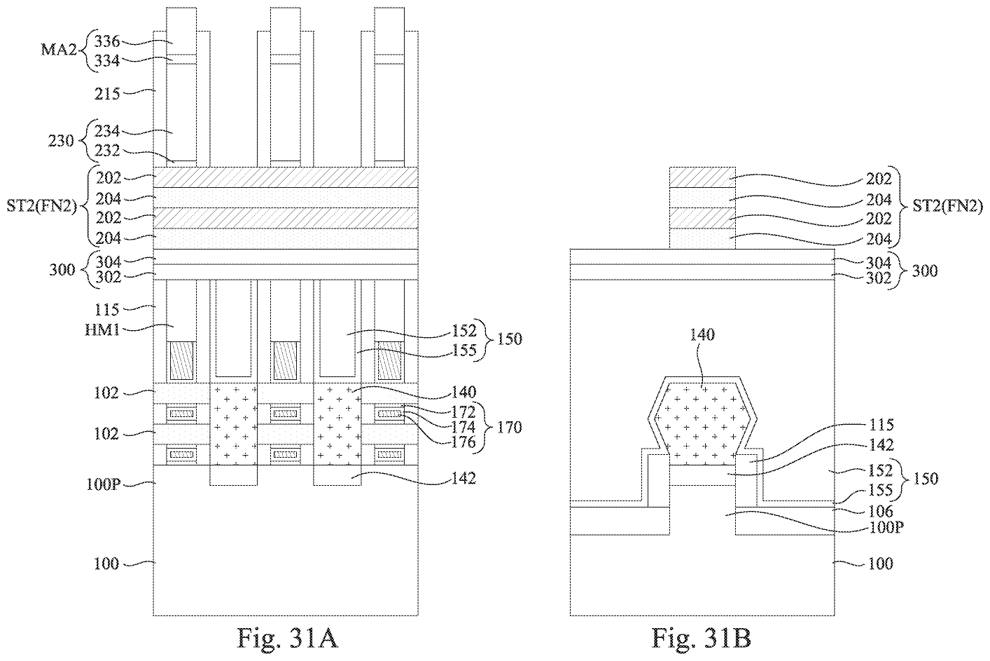

Reference is made to FIGS. 31A and 31B. Dummy gate structures 230 are formed crossing the fin structure FN2. In some embodiments, each of the dummy gate structures 230 includes a dummy gate dielectric 232 and a dummy gate electrode 234 over the dummy gate dielectric 232. The materials of the dummy gate dielectric 232 and the dummy gate electrode 234 may be similar to the materials of the dummy gate dielectric 132 and the dummy gate electrode 134, and thus relevant details will not be repeated.

The dummy gate electrode 234 and the dummy gate dielectric 232 may be formed by, for example, depositing a dummy dielectric layer and a dummy gate layer over the fin structure FN2, forming patterned masks MA2 over the dummy gate layer, and then performing an etching process to the dummy dielectric layer and the dummy gate layer by using the patterned masks MA2 as etch mask. In some embodiments, each of the patterned masks MA2 includes a first hard mask 334 and a second hard mask 336 over the first hard mask 334. In some embodiments, the first hard mask 334 may be formed of silicon nitride, and the second hard mask 336 may be formed of silicon oxide.

Spacers 215 are formed on opposite sidewalls of each of the dummy gate structures 230. The material and the formation method of the spacers 215 may be similar to those described with respect to the spacers 115, and thus relevant details will not be repeated.

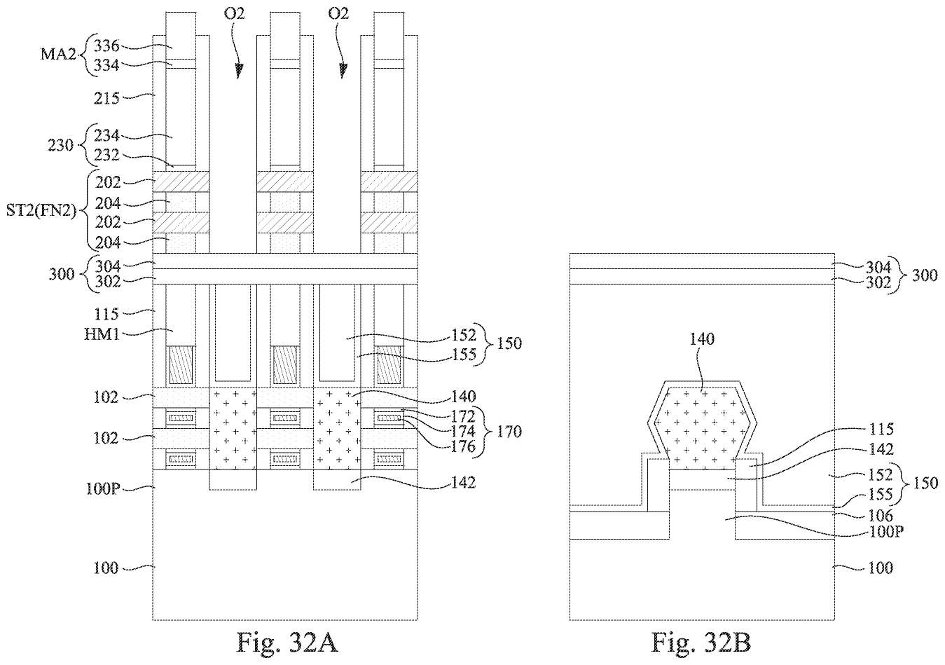

Reference is made to FIGS. 32A and 32B. An etching process is performed to remove portions of the fin structure FN2 (or stack ST2) by using the dummy gate structures 230 and the spacers 215 as etch mask, so as to form source/drain openings O2. Then, the sacrificial layers 204 are laterally etched to form sidewall recesses, and inner spacers 216 are formed in the sidewall recesses opposite ends of each of the sacrificial layers 204.

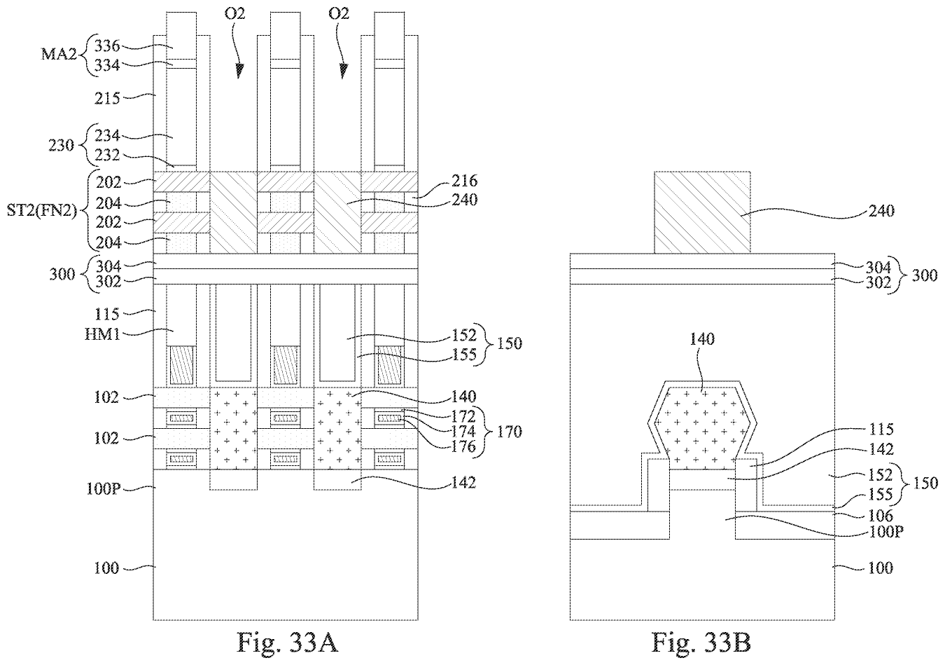

Reference is made to FIGS. 33A and 33B. Second source/drain structures 240 are formed on opposite ends of each of the metal oxide layers 202. In some embodiments, the second source/drain structures 240 may be made of metal, and can also be referred to as source/drain metals. The second source/drain structures 240 may be formed by, for example, depositing a metal layer in the source/drain openings O2, and then patterning the metal layer.

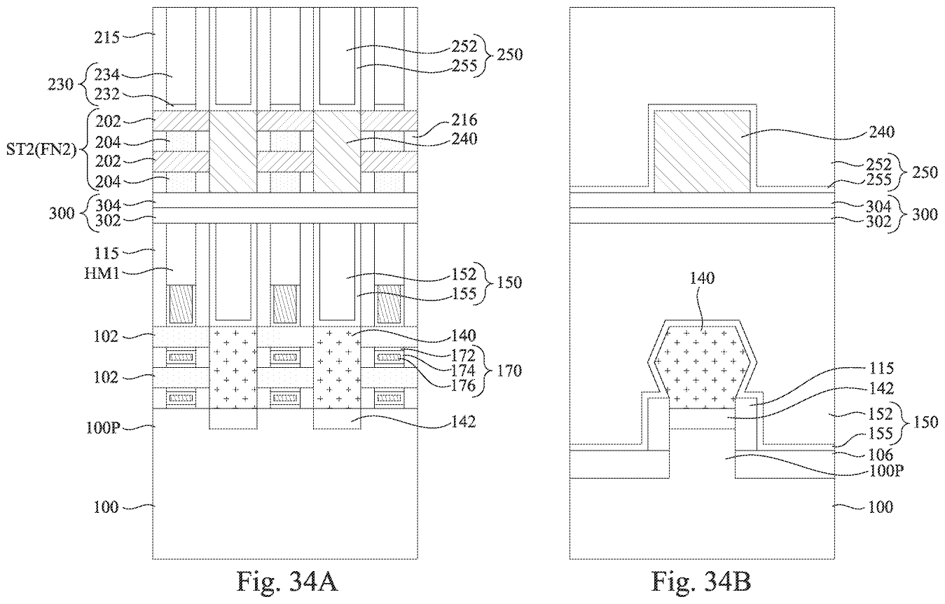

Reference is made to FIGS. 34A and 34B. A contact etch stop layer (CESL) 255 is formed covering the second source/drain structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 230 are exposed. In some embodiments, the patterned masks MA1 are removed during the planarization process. In some embodiments, the CESL 255 and the ILD layer 252 can be collectively referred to as an isolation structure 250.

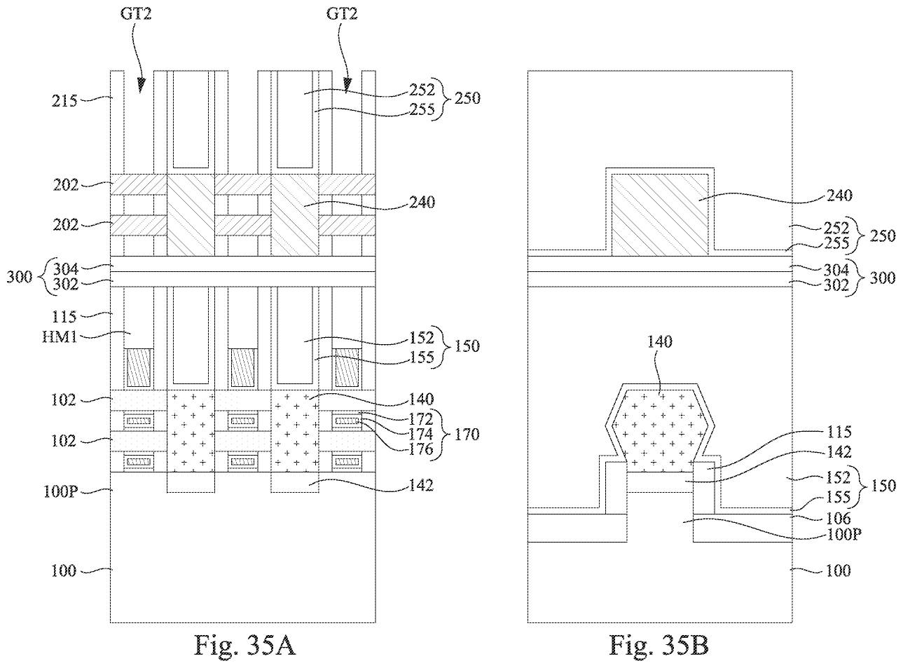

Reference is made to FIGS. 35A and 35B. The dummy gate structures 230 are removed to form gate trenches GT2 between each pair of the spacers 215. Then, an etching process is performed to remove the sacrificial layers 204 through the gate trenches GT2, such that that the metal oxide layers 202 are suspended over the bonding structure 300.

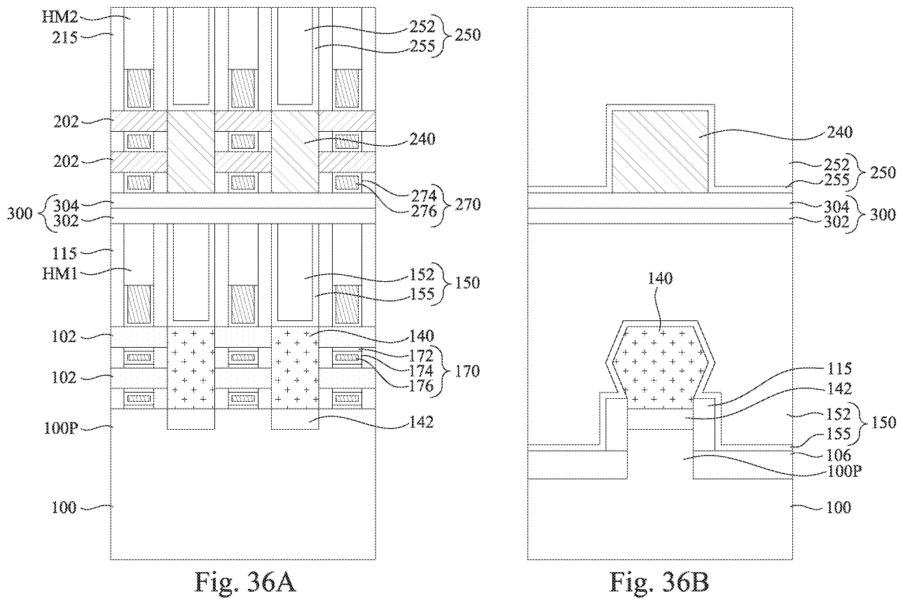

Reference is made to FIGS. 36A and 36B. Gate dielectric layers 274 are formed in the gate trenches GT2 and over the metal oxide layers 202, and gate electrodes 276 are formed over the gate dielectric layers 274. Accordingly, second gate structures 270 are formed, in which each of the second gate structures 270 includes a gate dielectric layer 274 and a gate electrode 276. A planarization process, such as CMP, is performed to remove the excess gate dielectric layers 274 and the excess gate electrodes 276 until the ILD layer 252 is exposed.

The second gate structures 270 are then etched back, such that top surfaces of the second gate structures 270 are lower than top surfaces of the spacers 215. Afterwards, hard masks HM2 are formed over the respectively second gate structures 270.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a CFET, which includes a first transistor and a second transistor above the first transistor. The second transistor may include metal oxide channel layer. The metal oxide channel layer may provide benefits such as high mobility, low thermal budget, and lattice mismatch free. With such configuration, the device performance may be improved.

In some embodiments of the present disclosure, a semiconductor device includes a first transistor and a second transistor vertically stacked over the first transistor. The first transistor includes a semiconductor channel layer, a first gate structure wrapping around the semiconductor channel layer, and first source/drain structures on opposite ends of the semiconductor channel layer. The second transistor includes a metal oxide channel layer, a second gate structure wrapping around the metal oxide channel layer, and second source/drain structures on opposite ends of the metal oxide channel layer.

In some embodiments, the first source/drain structures are made of epitaxy material, while the second source/drain structures are made of metal.

In some embodiments, the first transistor is a p-type transistor, while the second transistor is an n-type transistor.

In some embodiments, the semiconductor device further includes a semiconductor layer in contact with a bottom surface of the second gate structure.

In some embodiments, the semiconductor device further includes a metal oxide layer in contact with a bottom surface of the second gate structure.

In some embodiments, the semiconductor device further includes an isolation structure vertically between one of the first source/drain structures and one of the second source/drain structures, wherein the metal oxide layer is in contact with the isolation structure.

In some embodiments, the metal oxide layer is made of a same material as the metal oxide channel layer.

In some embodiments, the metal oxide channel layer comprises indium oxide (InOx), gallium oxide (GaOx), zinc oxide (ZnOx), tin oxide (SnOx), cadmium oxide (CdO), nickel oxide (NiO), copper oxide (CuO), or scandium oxide (ScOx).

In some embodiments of the present disclosure, a semiconductor device includes a first transistor and a second transistor vertically stacked over the first transistor. The first transistor includes a first channel layer, a first gate structure wrapping around the first channel layer, and source/drain epitaxy structures in contact with opposite ends of the first channel layer. The second transistor includes a second channel layer, wherein the first channel layer and the second channel layer are made of different materials, a second gate structure wrapping around the second channel layer, and source/drain metals in contact with opposite ends of the second channel layer.

In some embodiments, the first channel layer is made of semiconductor material, while the second channel layer is made of metal oxide.

In some embodiments, the first channel layer has a crystalline structure, while the second channel layer has an amorphous structure.

In some embodiments, the first gate structure comprises an interfacial layer, a first high-k dielectric layer over the interfacial layer, and a first gate electrode over the first high-k dielectric layer, the first high-k dielectric layer is separated from the first channel layer through the interfacial layer, the second gate structure comprises a second high-k dielectric layer and a second gate electrode over the second high-k dielectric layer, and the second high-k dielectric layer is in contact with the second channel layer.

In some embodiments, the semiconductor device further includes a bonding layer between the first transistor and the second transistor, wherein the bonding layer is in contact with the second gate structure and the source/drain metals.

In some embodiments, the bonding layer is made of a dielectric material.

In some embodiments, the semiconductor device further includes an isolation structure covering one of the source/drain metals and in contact with a top surface of the bonding layer.

In some embodiments of the present disclosure, a method includes forming a first stack of alternating first channel layers and first sacrificial layers over a substrate; forming a second stack of alternating second channel layers and second sacrificial layers over the first stack, wherein the second channel layers are made of metal oxide; forming first source/drain structures on opposite ends of each of the first channel layers; forming second source/drain structures on opposite ends of each of the second channel layers; removing the first sacrificial layers; forming a first gate structure wrapping around each of the first channel layers; removing the second sacrificial layers; and forming a second gate structure wrapping around each of the second channel layers.

In some embodiments, the second sacrificial layers are made of semiconductor material.

In some embodiments, the second sacrificial layers are made of dielectric material.

In some embodiments, the first source/drain structures are made of epitaxy material, while the second source/drain structures are made of metal.

In some embodiments, wherein the first channel layers are made of semiconductor material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor, comprising:
a semiconductor channel layer;
a first gate structure wrapping around the semiconductor channel layer; and
first source/drain structures on opposite ends of the semiconductor channel layer; and
a second transistor vertically stacked over the first transistor, comprising:
a metal oxide channel layer;
a second gate structure wrapping around the metal oxide channel layer; and
second source/drain structures on opposite ends of the metal oxide channel layer.

2. The semiconductor device of claim 1, wherein the first source/drain structures are made of epitaxy material, while the second source/drain structures are made of metal.

3. The semiconductor device of claim 1, wherein the first transistor is a p-type transistor, while the second transistor is an n-type transistor.

4. The semiconductor device of claim 1, further comprising a semiconductor layer in contact with a bottom surface of the second gate structure.

5. The semiconductor device of claim 1, further comprising a metal oxide layer in contact with a bottom surface of the second gate structure.

6. The semiconductor device of claim 5, further comprising an isolation structure vertically between one of the first source/drain structures and one of the second source/drain structures, wherein the metal oxide layer is in contact with the isolation structure.

7. The semiconductor device of claim 5, wherein the metal oxide layer is made of a same material as the metal oxide channel layer.

8. The semiconductor device of claim 1, wherein the metal oxide channel layer comprises indium oxide (InOx), gallium oxide (GaOx), zinc oxide (ZnOx), tin oxide (SnOx), cadmium oxide (CdO), nickel oxide (NiO), copper oxide (CuO), or scandium oxide (ScOx).

9. A semiconductor device, comprising:
a first transistor, comprising:
a first channel layer;
a first gate structure wrapping around the first channel layer; and
source/drain epitaxy structures in contact with opposite ends of the first channel layer; and
a second transistor vertically stacked over the first transistor, comprising:
a second channel layer, wherein the first channel layer and the second channel layer are made of different materials;
a second gate structure wrapping around the second channel layer; and
source/drain metals in contact with opposite ends of the second channel layer.

10. The semiconductor device of claim 9, wherein the first channel layer is made of semiconductor material, while the second channel layer is made of metal oxide.

11. The semiconductor device of claim 9, wherein the first channel layer has a crystalline structure, while the second channel layer has an amorphous structure.

12. The semiconductor device of claim 9, wherein,
the first gate structure comprises an interfacial layer, a first high-k dielectric layer over the interfacial layer, and a first gate electrode over the first high-k dielectric layer, the first high-k dielectric layer is separated from the first channel layer through the interfacial layer,
the second gate structure comprises a second high-k dielectric layer and a second gate electrode over the second high-k dielectric layer, and the second high-k dielectric layer is in contact with the second channel layer.

13. The semiconductor device of claim 9, further comprising a bonding layer between the first transistor and the second transistor, wherein the bonding layer is in contact with the second gate structure and the source/drain metals.

14. The semiconductor device of claim 13, wherein the bonding layer is made of a dielectric material.

15. The semiconductor device of claim 13, further comprising an isolation structure covering one of the source/drain metals and in contact with a top surface of the bonding layer.

16. A method, comprising:
forming a first stack of alternating first channel layers and first sacrificial layers over a substrate;
forming a second stack of alternating second channel layers and second sacrificial layers over the first stack, wherein the second channel layers are made of metal oxide;
forming first source/drain structures on opposite ends of each of the first channel layers;
forming second source/drain structures on opposite ends of each of the second channel layers;
removing the first sacrificial layers;
forming a first gate structure wrapping around each of the first channel layers;
removing the second sacrificial layers; and
forming a second gate structure wrapping around each of the second channel layers.

17. The method of claim 16, wherein the second sacrificial layers are made of semiconductor material.

18. The method of claim 16, wherein the second sacrificial layers are made of dielectric material.

19. The method of claim 16, wherein the first source/drain structures are made of epitaxy material, while the second source/drain structures are made of metal.

20. The method of claim 16, wherein the first channel layers are made of semiconductor material.
